(19) United States
(12) Patent Application Publication
(10) Pub. No.: US 2026/0215225 A1
(43) Pub. Date: Jul. 23, 2026

(54) AUTOMATED RECIPE HEALTH OPTIMIZATION

(71) Applicant: Lam Research Corporation, Fremont, CA (US)

(72) Inventors: Roger Wang, Fremont, CA (US); Travis Joseph Wong, Oakland, CA (US); Justin Tang, Todoroki (JP); John Valcore, JR., Worthington, OH (US); Adrian Esteban Sapio, Spicewood, TX (US); Aravind Alwan, Milpitas, CA (US); Ying Wu, Livermore, CA (US); Junghyup Hong, Livermore, CA (US); Jilai Ding, Milpitas, CA (US)

(21) Appl. No.: 19/144,045

(22) PCT Filed: Dec. 29, 2023
(86) PCT No.: PCT/US2023/086485

§ 371 Date: Jun. 27, 2025

Related U.S. Application Data
(60) Provisional application No. 63/478,072, filed on Dec. 30, 2022.

(51) Int. Cl. H10P 74/20

(52) U.S. Cl. CPC H10P 74/20

(57) ABSTRACT

Process recipes have process parameter values for each step of the recipe. Recipes may be validated to determine if it can be stably implemented. A recipe that is considered invalid may be optimized to determine minimum or maximum setpoints for the recipe, which may differ from the setpoints determined to be valid by the initial validation. The recipe may also be optimized to determine recipe margin and optimal process parameter values for process parameters of a step in the recipe.

### RELATED APPLICATIONS

A PCT Request Form is filed concurrently with this specification as part of the present application. Each application that the present application claims benefit of or priority to as identified in the concurrently filed PCT Request Form is incorporated by reference herein in its entirety.

### BACKGROUND

Driven by ever smaller technology nodes, semiconductor device fabrication systems constantly advance. Process recipes are developed, validated, and used to create new devices. Process recipes tend to be complex and are usually developed based on the knowledge and experience of process engineers. The system a process recipe is developed with may be different from a system that the process recipe is executed upon, which may cause the process recipe to not perform as expected.

Background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

In one aspect of the embodiments herein, a method is provided, including: (a) receiving a first recipe for a semiconductor fabrication operation, the first recipe including a plurality of steps, each step having one or more process parameters and each process parameter having a corresponding parameter value; (b) identifying a step of the first recipe; (c) performing the step a plurality of times, each performance using different parameter values for one or more process parameters associated with the step; (d) identifying sensor data associated with each performance of the step; (e) determining an optimal parameter value for at least one process parameter based on the sensor data; and (f) associating the optimal parameter value with the first recipe.

In some embodiments, the method further includes, before (b), providing the first recipe to one or more validation models, wherein each validation model outputs a health indicator. In some embodiments, a first validation model outputs a first health indicator that exceeds a first threshold value, wherein the first threshold value represents a threshold where the first recipe may be stably executed. In some embodiments, the method further includes determining, based on the optimal parameter value, that the first recipe may be stably implemented. In some embodiments, the method further includes updating the first recipe based on the optimal parameter value. In some embodiments, the optimal parameter value represents a recipe margin. In some embodiments, the method further includes (g) performing the first recipe based on the optimal parameter values, wherein during performance of the first recipe a second health indicator exceeds a second threshold value, and (h) generating a report indicating the second health indicator exceeded the second threshold value. In some embodiments, the second health indicator represents a plurality of sensor data, and the report indicates one or more sensor data that most contributed to the second health indicator exceeding the second threshold value. In some embodiments, the method is performed during qualification of a process recipe.

In another aspect of the embodiments herein, a method is provided, the method including: (a) receiving a recipe for a semiconductor fabrication operation, the recipe including a plurality of steps, each step having one or more process parameters and each process parameter having a corresponding parameter value; (b) identifying a first step of the first recipe; (c) performing the first step using a fabrication tool, wherein during performing of the step one or more cycles are performed of: (i) identifying sensor data associated with performing the first step; (ii) determining one or more health indicators based on the sensor data; and (f) modifying one or more process parameter values of the first step based on the one or more health indicators and the sensor data.

In some embodiments, the one or more health indicators each represent a plurality of sensor data. In some embodiments, the one or more cycles are performed until the health indicator converges on a maximum or minimum value. In some embodiments, the modified one or more process parameter values are saved to the first recipe after the health indicator converges. In some embodiments, the health indicators are also based on a baseline health indicator metric, wherein the baseline health indicator metric is a health indicator associated with the first step for a prior performance of the first step. In some embodiments, the prior performance of the first step is with a different fabrication tool than the fabrication tool performing the first step. In some embodiments, modifying one or more process parameter values of the first step is additionally based on the one or more health indicators exceeding a threshold value. In some embodiments, modifying one or more process parameter values of the first step is additionally based on the one or more health indicators exceeding the threshold value for a pre-determined duration. In some embodiments, the one or more cycles are not performed for an initial duration of performing the first step. In some embodiments, the method further includes generating a report of failure modes for the first step of the recipe based on process parameters for the first step and sensor data collected during performance of the first step. In some embodiments, a first failure mode indicates one or more sensor data that contributed to a first health indicator exceeding a threshold value.

In another aspect of the embodiments herein, a system for optimizing a recipe is provided, the system including: a process chamber; and one or more processors configured for: (a) receiving a recipe for a semiconductor fabrication operation, the recipe including a plurality of steps, each step having one or more process parameters and each process parameter having a corresponding parameter value; (b) identifying a first step of the first recipe; (c) performing the first step in the process chamber, wherein during performing of the step one or more cycles are performed of: (i) identifying sensor data associated with performing the first step; (ii) determining one or more health indicators based on the sensor data; and (f) modifying one or more process parameter values of the first step based on the one or more health indicators and the sensor data.

These and other features of the disclosed embodiments will be described in detail below with reference to the associated drawings.

### BRIEF DESCRIPTION OF DRAWINGS

FIG. 1 presents an example recipe according to various embodiments herein.

FIGS. 2A-2C present a process flow for optimizing parameters of a recipe according to various embodiments herein.

FIG. 3 presents a chart of radio-frequency (RF) power vs conductance.

FIG. 4 presents a chart of RF power vs confinement ring position.

FIG. 5 presents a chart of pressure and RF reflection coefficient over time.

FIG. 6A presents a schematic diagram of a system for determining health characteristics according to various embodiments herein.

FIG. 6B presents a chart of failure modes for a recipe.

FIG. 6C presents a time series chart of a health indicator score for a recipe.

FIG. 7 presents a schematic diagram of a processing system for performing various embodiments herein.

### DETAILED DESCRIPTION

### Context

Some disclosed embodiments afford flexibility in deploying variations of recipes that were previously qualified for device fabrication tools having specific configurations. Some disclosed embodiments afford flexibility in changing one or more device fabrication tool parameters without requalifying a recipe that was previously qualified for an original tool configuration. In the past, the tool and recipe ecosystem inflexibly forced the tool to have a particular group of parameter settings in order for the recipe to validly execute. For example, if a customer made a minor change to the process conditions under which it performed a particular process, such as in ALD process, this variation of an original or qualified recipe might be deemed invalid. In order to afford the tool user (e.g., an IC fabrication facility) more flexibility to vary parameters associated with a given tool or group of tools and still safely use the variant recipe, a tool user and/or device fabrication tool vendor may employ embodiments disclosed herein.

In some embodiments a recipe may be validated based on various models that analyze process parameter values of the recipe. These models may be simplified and biased towards under-inclusion, such that recipes that may be validly executed are considered invalid. A recipe may be actively validated against sensor data from depth of experiment tests to determine a more accurate assessment of whether the recipe can be validly executed.

### Terminology

Process parameter—A process parameter is a parameter that characterizes the performance of a process in a device fabrication tool. Examples of process parameters include process conditions such temperature (pedestal, wafer, showerhead, chamber wall, etc.), pressure within a chamber, plasma properties (power, frequency(ies), pulse characteristics, bias, etc.), process gas properties (composition, flow rate, etc.), and duration or time of particular operations (etch process, number of ALD or ALE cycles), etc.).

Sensor data—Sensor data includes information collected by sensors deployed throughout a semiconductor fabrication process. Sensors may collect data such as temperature, pressure, mass flow, etc. Sensors may also collect data regarding electrical properties, e.g., frequency, power, voltage, current, and reflection coefficient. In some embodiments, sensor data may include derivative information or statistics that are determined based on other sensor data, such as a variability of a DC bias voltage during a time window.

Recipe—A recipe is a set of process parameter values under which a fabrication operation or a portion of a fabrication operation is to be practiced. A recipe may work (successfully execute a process) on one or more device fabrication tools having one or more configurations, which configurations are sometimes referred to herein as “fingerprints.” Examples of process parameters having values collectively provided in a recipe include chamber pressure, process gas flow rate, process gas composition, pedestal temperature, plasma power, and duration of the process. In various embodiments, a recipe is a set of conditions within a “process window” of a device fabrication tool. In such embodiments, the recipe may represent a single point in a process window. In other words, a recipe may represent a collection of discrete parameters values rather than ranges of such values. In certain embodiments, a recipe of a multi-step process may include a series of discrete process space points, with one point for each step. Even simple, non-cyclic processes may have multi-step recipes. For example, an etch process may have a recipe that includes (a) an initial set up step that defines wafer handling before or during introduction of a wafer to an etch chamber, and (b) an etch process step that defines process conditions in the etch chamber while the wafer is being etched.

Recipe Margin—A recipe margin describes a range of process parameter values associated with a given tool that defines the realm of process parameter space in which the recipe can be stably implemented. Outside of this range, the process may become unstable or otherwise not function properly. For example, outside of its margin, a process may not support a stable plasma. A recipe margin may be represented by a single parameter value, such as a minimum or maximum pressure, or by a combination of parameter values, e.g., a combination of gas flow, pressure, and RF power.

Fingerprint—A fingerprint represents a particular set of tool parameter values of a device fabrication tool. In some embodiments, a fingerprint is single collection of discrete tool parameter values, rather than a range of such values. As an example, a fingerprint may be a unique set of hardware, firmware, and/or software for each of several components that together comprise the tool. A fingerprint may be provided for a particular recipe that was developed or qualified using a tool having the fingerprint. A fingerprint may include one or more of: software configuration options, software configuration variables, firmware versions, hardware configurations, alarm policies, scheduler policies, calibration files, compensation files, and data log signals.

Model—A model is a set of rules or other algorithm or logic for determining whether a given recipe is suitable for implementation on a particular tool component or collection of tool components, which may collectively have a particular fingerprint. In some embodiments, a model is configured to determine whether a given recipe can be deployed or continued to be deployed on a particular tool having a particular combination of settings or other parameters. A model may be configured to receive a recipe and a current tool parameter value or values. In some embodiments, a model may be configured to output an optimized parameter value for one or more steps of a recipe. In some embodiments, a model may be configured to output a health characteristic of a tool component performing the recipe. The health characteristic may indicate whether the tool component can successfully carry out the recipe.

Failure Mode—A failure mode represents a root cause of how a recipe, step of a recipe, or state of a step is considered unhealthy. In some embodiments, a failure mode may be determined based on one or more models used for determining health characteristics. A health characteristic may exceed a threshold value, indicating a portion of a recipe is unhealthy. A failure mode may represent the root cause for the health characteristic exceeding the threshold value. A failure mode may include information on which step or state and what sensor data caused the health characteristic to exceed the threshold value. In some embodiments, a failure mode may include information on the expected sensor data or expected statistics derived from sensor data, e.g., the variability of a bias voltage. If the variability exceeds a pre-determined value, then a health indicator based on the variability will change. In some embodiments, a failure mode may include process parameters related to the sensor data that caused the health characteristic to exceed the threshold value. Failure modes are helpful to identify the specific sensor data and/or process parameters that caused a health indicator to exceed a threshold and the recipe/step/state to be considered unhealthy. In some embodiments, a failure mode may be recovered automatically by pre-determined rules for modifying one or more process parameters based on a specific failure mode. In other embodiments, a failure mode may be part of a notification generated that a process engineer or other person may use to modify a recipe or potentially modify a tool on which the recipe is being performed, e.g., replace a consumable part.

Health Characteristic or Health Indicator—A health characteristic or health indicator represents a set of rules or other algorithms or logic applied to a fingerprint and/or recipe, particularly when attempting to run a recipe. During the execution of a recipe, hundreds of signal parameters/sensor data (e.g., bias voltage, gas pressure, radio frequency, etc.) may be collected. These signals may be analyzed to determine whether a recipe is successfully executing. However, reviewing all of the signal parameters is resource intensive. Thus, the sensor data or a subset of sensor data may be analyzed to determine one or more health indicators that may be used to determine whether a recipe is successfully executing. In some embodiments, a health indicator may be associated with a health threshold. In some embodiments, if the health indicator exceeds the health threshold a notification may be generated to alert a user that the health indicator has exceeded the threshold. In some embodiments, if the health indicator exceeds the health threshold a modification to the recipe is automatically implemented to recover the health indicator within the health threshold.

In some embodiments, if the health indicator cannot be recovered then a notification may be generated. In some implementations, the notification may include potential causes of the health indicator exceeding the threshold, e.g., failure modes. For example, a health indicator associated with a pressure sensor in line with a gas delivery manifold may exceed a value, and potential causes may include clogging of an inlet to a process chamber, erosion of the piping or various valves, degradation of a pumping system, or a mis-calibrated mass flow controller. In some embodiments, the health indicator may be recovered by varying process parameters. In other embodiments, the health indicator may not be recovered without implementation of a hardware change or a process to modify the tool, e.g., performing a chamber clean process or replacement of a part within the tool.

A “semiconductor device fabrication operation” or “fabrication operation,” as used herein, is an operation performed during fabrication of semiconductor devices. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition). In the context of etch processes, a substrate etch process includes processes that etch a mask layer or, more generally, processes that etch any layer of material previously deposited on and/or otherwise residing on a substrate surface. Such etch process may etch a stack of layers in the substrate.

“Manufacturing equipment” or “fabrication tool” refers to equipment in which a manufacturing process takes place. Manufacturing equipment may include a processing chamber in which the workpiece resides during processing. Typically, when in use, manufacturing equipment performs one or more semiconductor device fabrication operations, which may be performed according to a “recipe.” Examples of manufacturing equipment for semiconductor device fabrication include subtractive process reactors and additive process reactors. Examples of subtractive process reactors include dry etch reactors (e.g., chemical and/or physical etch reactors), wet etch reactors, and ashers. Examples of additive process reactors include chemical vapor deposition reactors, and atomic layer deposition reactors, physical vapor deposition reactors, and electroplating cells. Device fabrication tools typically comprise various subsystems, such as an RF source, temperature controller, gas delivery, pressure controller, etc.

### Recipe Optimization

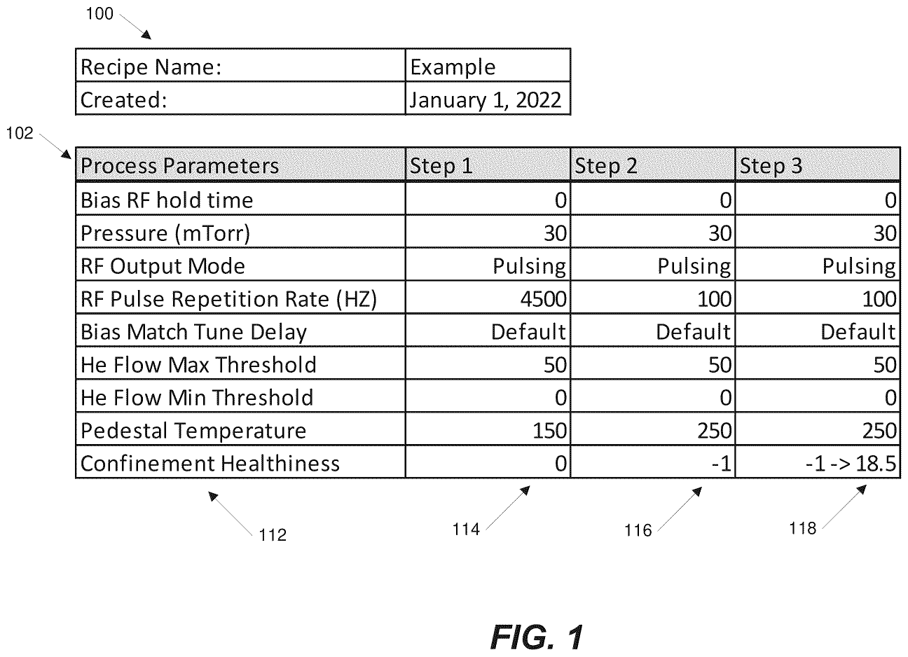

FIG. 1 shows an example of a recipe 100 having three steps. For each of steps 1, 2, and 3, a value is associated with each process parameter 102. It should be understood that a recipe conventionally has many more process parameters and additional steps than shown in FIG. 1. In some embodiments, the value associated with a process parameter may depend from or refer to another module. For example, the Bias Match Tune Delay process parameter is associated with a “Default” value, which may refer to a separate module. In some embodiments, the dependencies may refer to best known method “BKM” modules. A BKM module may allow a user editing a recipe to automatically refer to the BKM process parameter values for particular process parameters and particular steps.

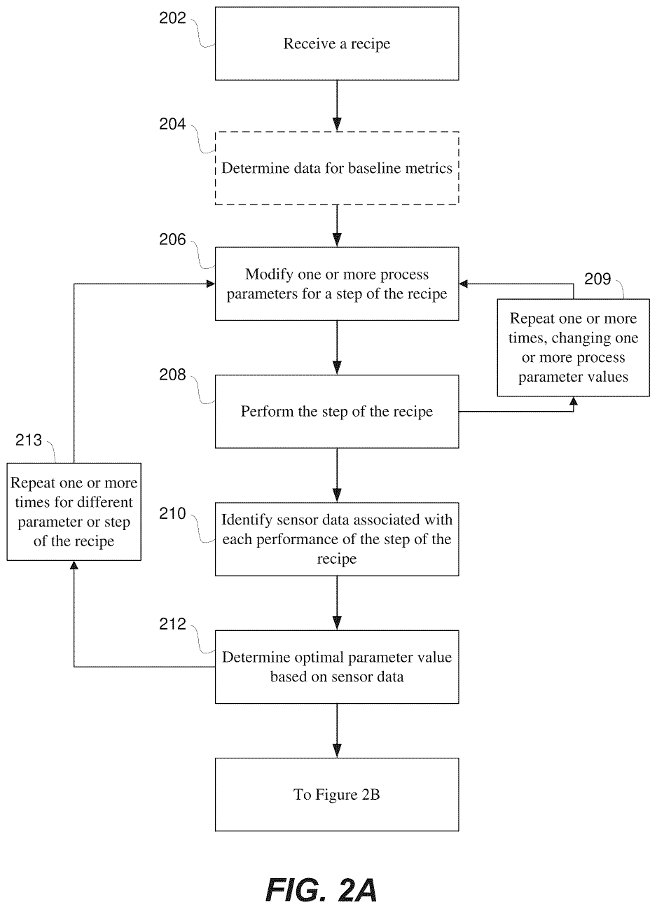

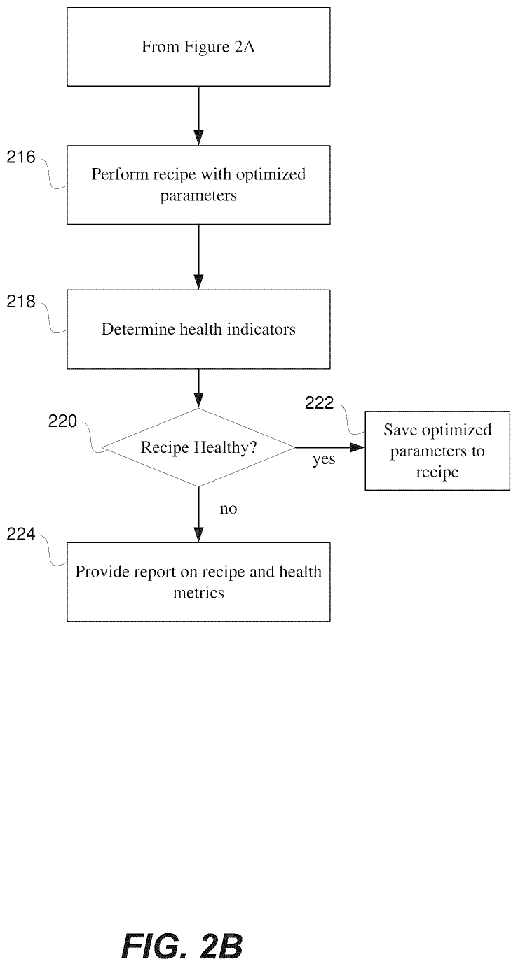

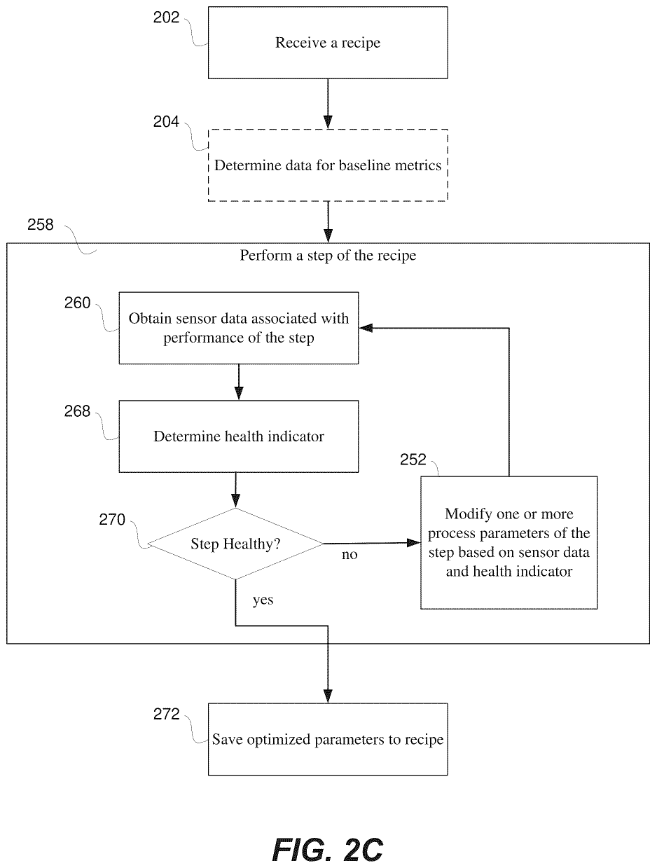

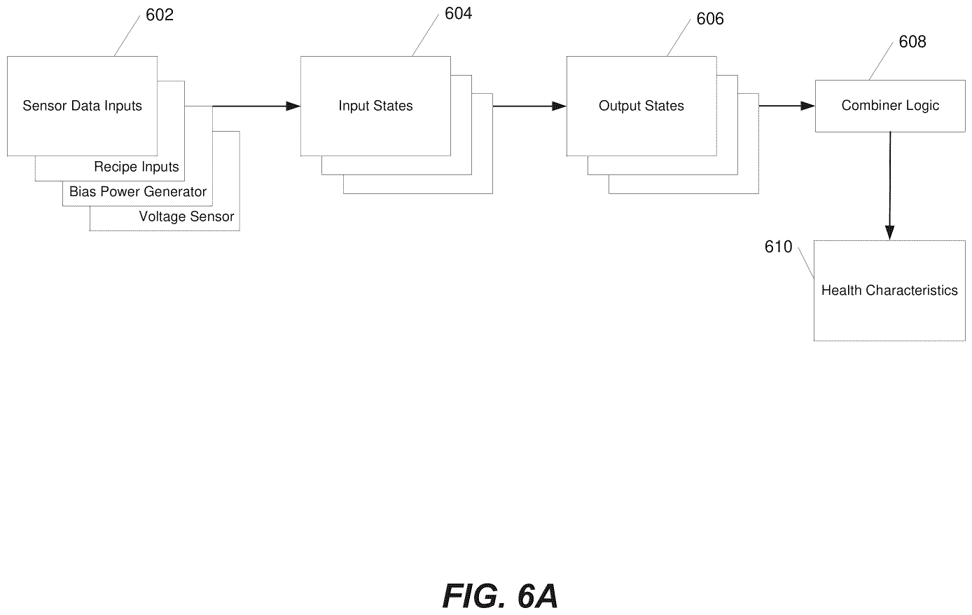

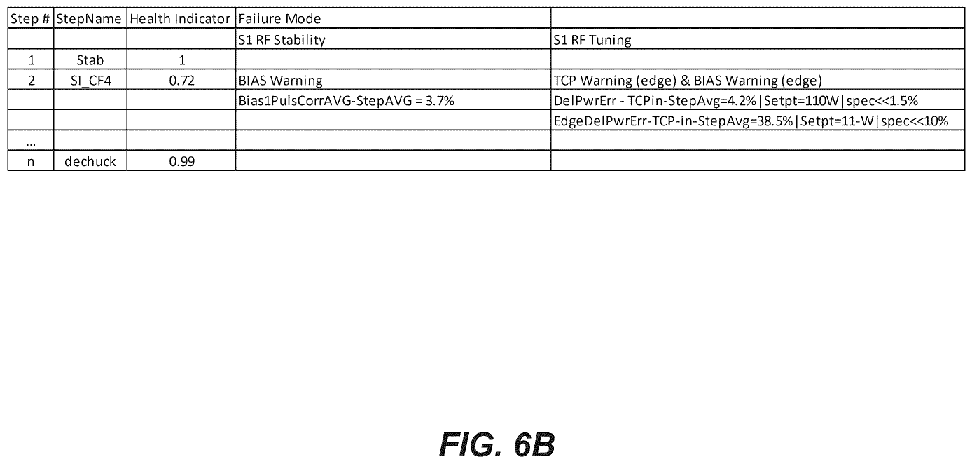

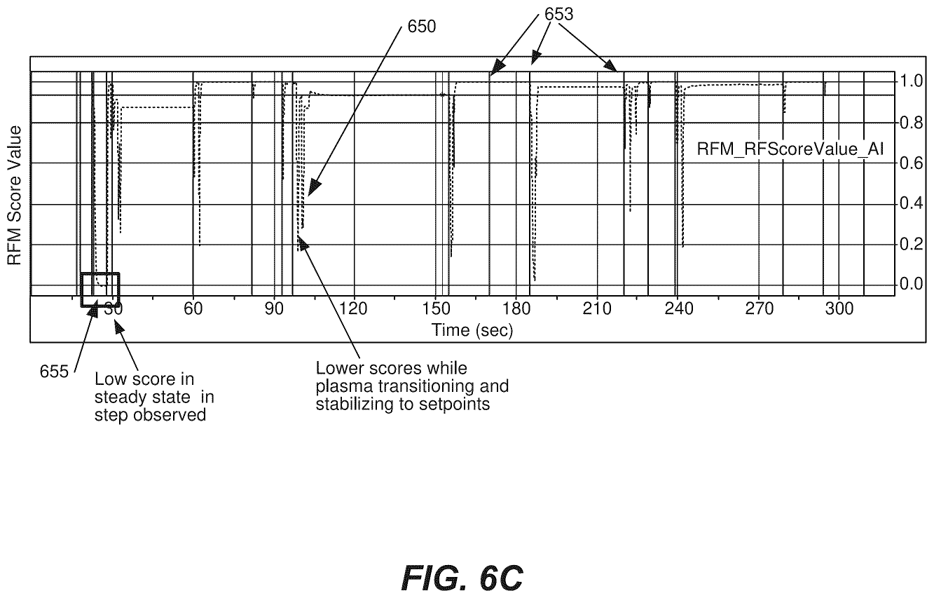

Recipe 100 may also include various health indicators. Confinement healthiness 112 is an example health indicator that relates to whether a plasma generated during the execution of recipe 100 is confined. A plasma may become unconfined for various reasons, and plasma unconfinement may be undesirable. Thus, confinement healthiness scores 114, 116, and 118 indicate whether the plasma may become unconfined during that step. In the example of FIG. 1, a ‘0’ indicates the step has not been analyzed for healthiness, a −1 indicates the plasma is unconfined (i.e., ‘unhealthy’), and a value >0 indicates a threshold that should be maintained as a minimum value, a maximum value, or a range of values. In FIG. 1, the 18.5 value in step 3 for confinement healthiness may indicate a minimum pressure that should be maintained to generate a confined plasma. In some embodiments, a health indicator may represent a minimum, maximum, or range of values for a process parameter. In other embodiments, a health indicator may represent that a step may be performed while the health indicator exceeds a threshold value. The 18.5 value may be determined by using various processes described herein. In FIG. 1 confinement healthiness score 118 is presented as “−1->18.5.” This is intended to represent an initial determination of unhealthy, which is then updated to a threshold value of 18.5 by performing processes described herein. While a single health indicator is shown for each step in FIG. 1, in some embodiments a health indicator may be determined as a time series for a recipe with multiple health indicators determined during a step, as shown in FIG. 6C, discussed further below. In some embodiments, a health indicator may be normalized to a value between 0 and 1, where a step is considered “healthy” as long as the normalized value is greater than a threshold, e.g., 0.8. Various threshold may be used. In some embodiments, thresholds may be determined based FIGS. 2A-B present a flowchart for determining optimized parameters for a recipe. In some embodiments, optimized parameters may represent parameter values that best achieve a desired result. In other embodiments, optimized parameters may represent a recipe margin, where a recipe may be stably implemented within the optimized parameters. Starting in FIG. 2A, a recipe is received (202). A recipe may be represented as shown in FIG. 1, e.g., a series of steps with process parameter values for various process parameters. In some embodiments, the process of FIG. 2A-B may be performed as part of qualification of a recipe. Recipe qualification may involve determining that the recipe may be stably run and is healthy for each step of the recipe.

In some embodiments, the recipe may be performed and/or analyzed to determine baseline metrics (204). Baseline metrics may include sensor data and health indicators. In some embodiments, baselines metrics may include an initial determination that a recipe is unhealthy. For example, if a health indicator is determined to exceed a threshold, then a recipe, or a step of the recipe, may be considered to be unhealthy. Healthiness may be recipe specific, and a recipe may have multiple health indicators. For example, in FIG. 1 the recipe may be unhealthy at step 2 and step 3 based on the −1 value for confinement healthiness.

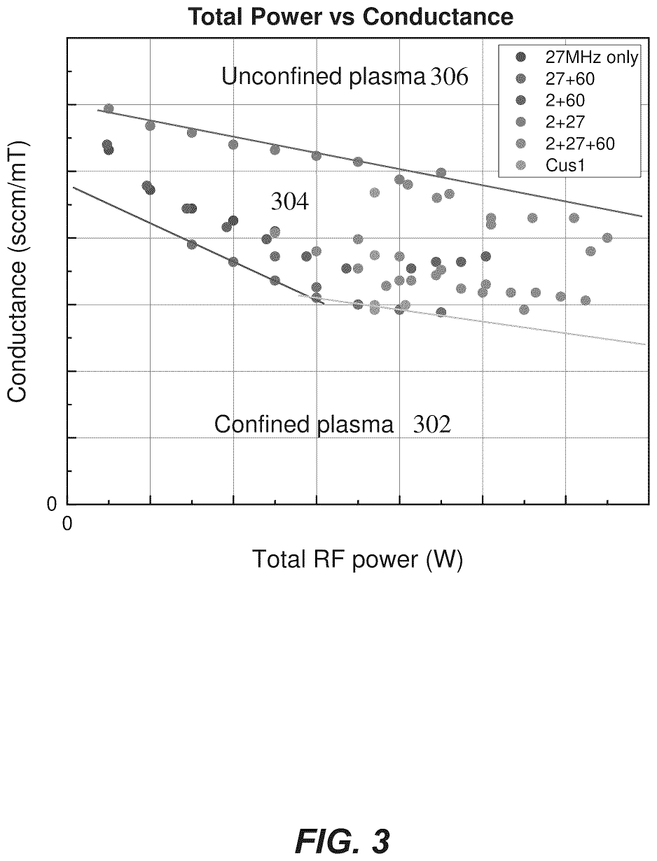

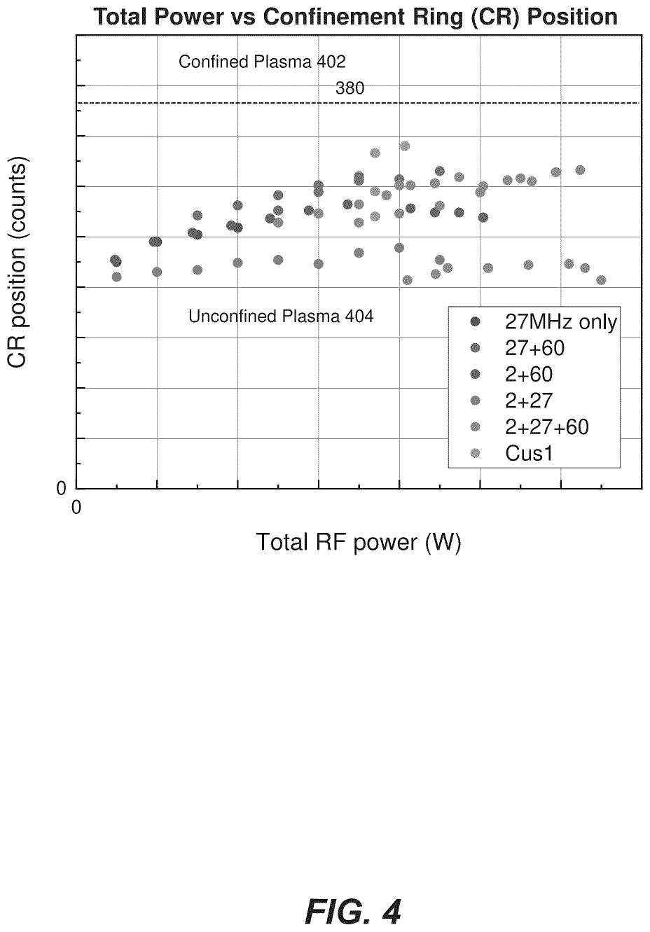

In some embodiments, baseline metric healthiness may be assessed using models. These models may be used to validate a recipe deterministically; the recipe parameters may be analyzed to determine whether the process parameter values fall within ranges previously determined to be healthy. In some embodiments, these models may use thresholds for combinations of process parameter values. FIGS. 3 and 4 present examples of such models. FIG. 3 presents power/conductance curves that distinguish between a confined plasma zone 302, an unconfined plasma zone 306, and a potentially unconfined plasma zone 304. While RF power and conductance are shown here, additional parameters such as total gas flow or pressure may also be considered. If the process parameter values of a recipe fall within the zone of confined plasma, then the recipe may be successfully validated (or at least validated in regards to a confined plasma). Alternatively, if the process parameter values fall within the unconfined plasma zone or potentially unconfined plasma zone, the recipe may be considered unhealthy or potentially unhealthy. FIG. 4 presents a similar graph of RF power and confinement ring position, where specific combinations of RF power and confinement ring position may be determined to result in a confined plasma, an unconfined plasma, or a potentially unconfined plasma. An unconfined plasma zone 404 and a confined plasma zone 402 may be defined based on confinement ring position and total RF power. In some embodiments, total gas flow and pressure may also affect whether the model successfully validates the recipe. For example, If the process parameter values fall within the unconfined plasma zones or the potentially unconfined plasma zones of FIGS. 3 and 4, a recipe may fail to validate. Furthermore, in some embodiments, models based on FIGS. 3 and 4 may be a series of thresholds for various process parameters, and if any pre-determined combinations of threshold are exceeded the recipe may be considered unhealthy based on the plasma being unconfined. This may occur even if the recipe could be executed with a confined plasma at the current process parameters. A recipe may fail to validate based on the models used for validation but would actually successfully run.

A recipe could be considered unhealthy based on the validation models but still successfully run because the models used for validating recipes do not necessarily reflect the exact configuration of a tool at a fabrication site or account for every process parameter, and thus a recipe may fail to validate that could actually successfully run. Alternatively, current process parameter values for a recipe may result in an unconfined plasma, but it may be helpful to suggest a minimum or maximum setpoint for process parameter values that result in a confined plasma rather than merely generating a notification that the recipe cannot generate a confined plasma. Furthermore, in some embodiments the models used for validation may be unable to determine a recipe margin for a recipe.

For example, a model used to validate a recipe may determine steps 2 and 3 of the recipe shown in FIG. 1 are invalid as the plasma would be unconfined. However, as shown in FIG. 1 and discussed further herein, the recipe may be stably executed at a pressure of at least 18.5 m Torr. As step 3 has a pressure of 30 mTorr, step 3 should be stably executed based on the updated optimal parameter determined based on embodiments discussed herein despite the validation model stating it would be unhealthy. Embodiments disclosed herein may be used to determine this recipe margin at greater specificity than a deterministic model used for initial validation of a recipe. This recipe margin may then be saved to the recipe as an exception to the validation models and as a more specific indicator of a stable process window for the recipe.

In some embodiments, the baseline metrics or recipe validation may be used to determine which process steps may need to be analyzed further. For example, if a process step is initially considered healthy, it may not be further analyzed or optimized. Alternatively, if a process step is considered invalid the process step may be further analyzed to determine optimal parameter values. In some embodiments process steps may be manually selected for analysis.

Returning to FIG. 2A, a recipe may be optimized by modifying one or more steps of the recipe, performing the modified steps, and collecting sensor data associated with the modified step. As shown in blocks 206, 208, and 209, a step of a recipe may be modified and performed multiple times, each time with a different process parameter value. In some embodiments, a test recipe may be determined that repeats a single step multiple times, e.g., ten or more times, where each repetition modifies one or more process parameters. Sensor data associated with the performance of the step with each process parameter value may then be collected (210) and used to determine an optimal parameter value (212). Sensor data may be health indicators, e.g., a parameter that is derived from various signals, or may be the original sensor data from one or more sensors. In some embodiments a specific set of sensor data is collected.

This flow may be repeated for various process parameters or various steps of a recipe (213). In some embodiments, blocks 206-212 may be performed for any health indicator that is considered unhealthy in step 204. In some embodiments, blocks 206-212 may be triggered manually by a user to determine optimal parameter values for specific process parameters and/or steps of a recipe. Blocks 206-212 may be performed as a design of experiment (DOE) analysis over a range of process parameter values for one or more process parameters.

The sensor data may then be used to determine optimal parameter values (212). Optimal parameter values may represent a specific setpoint for a recipe or a recipe margin. The recipe margin may indicate a stable process window for the process parameters. In some embodiments, a recipe is not modified based on the recipe margin, rather the recipe margin is associated with the recipe to aid a process engineer in determining whether a combination of parameter values are stable.

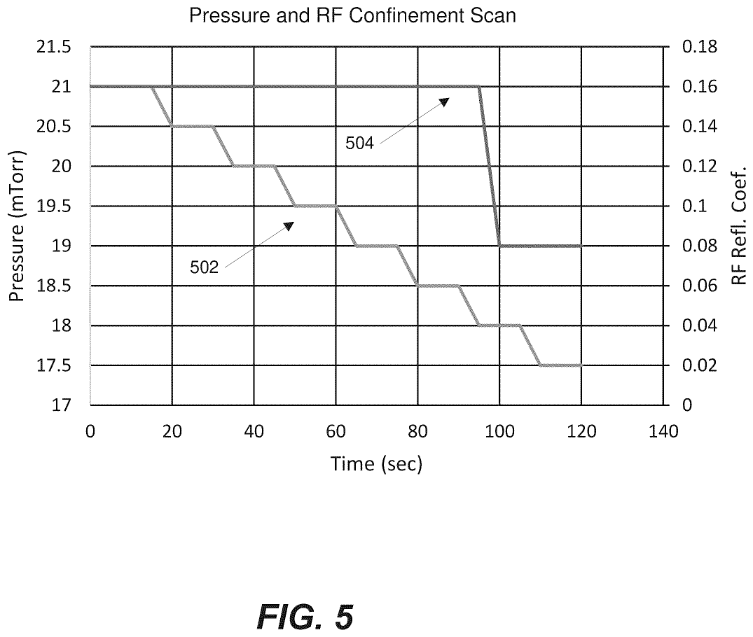

FIG. 5 presents an example of modifying a pressure step during a step of a recipe to determine an optimal pressure. In FIG. 5, a pressure of a process chamber may be stepped from 21 m Torr to 17.5 m Torr while a plasma is generated. The left axis and line 502 represent pressure, while the right axis and line 504 represent an RF reflection coefficient. Each change of pressure reflects a different parameter value for pressure for the same step of a recipe, e.g., step 3 of recipe 100. The recipe step repeated in FIG. 5 is performed to determine the relationship between pressure and confinement of a plasma. Thus, sensor data or health indicators relevant to plasma confinement may be collected. RF reflection coefficient may be an example of a health indicator or sensor data that is relevant to plasma confinement. RF reflection coefficient may correlate strongly with the confinement of a plasma, such that if the RF reflection coefficient changes rapidly as the pressure is modified, that may indicate the plasma is becoming or has become unconfined. Thus, as shown in the graph of FIG. 5, when the pressure decreases to 18 mTorr, the RF reflection coefficient similarly shows a sharp change from 0.16 to 0.08. This change may be interpreted to represent a change in the plasma, in particular that the plasma is unconfined. While a single sensor data is shown in FIG. 5, in some embodiments a plurality of sensor data may be identified and collected for analysis. In some implementations, the sensor data and/or health indicators may be pre-determined as relevant to a healthiness metric of interest, e.g., plasma confinement.

Optimal parameter values as used herein may refer to various types of process parameter values. In some embodiments, an optimal parameter value may be a minimum or maximum process parameter value for a recipe to run in a pre-determined stable state, e.g., a recipe margin. A stable implementation may be defined by health indicators, e.g., confinement of a plasma, which may itself be defined by a combination of sensor data. In other embodiments, an optimal parameter value may be a particular setpoint value from an objective function applied over a range of process parameter values to maximize a value of interest, e.g. maximize a health indicator.

Returning to FIG. 2A, the sensor data may be analyzed to determine optimal parameter values (212). Optimal parameter values may be determined using various statistical analysis or objective functions over collected sensor data. For example, a change in RF reflection greater than a threshold amount may indicate a change in the properties of the plasma, e.g., it has become unconfined.

In some embodiments, the optimal parameters may represent a minimum or maximum parameter value. As shown in FIG. 5, a pressure less than 18.5 m Torr causes a change in the RF reflection coefficient that indicates the plasma is unconfined. Thus, the optimal parameter value is a pressure of at least 18.5 mTorr. While a single parameter value is shown in FIG. 5, in some implementations multiple parameters may be optimized. For example, assuming pressure and RF power each affect the confinement of a plasma, the optimal parameters may be threshold values for pressure and RF power as a function of each other, e.g., if the RF is less than 2000 W then the pressure must be at least 18.5 m Torr, but the RF power is greater than 3000 W the pressure must be at least 16 mTorr. In some embodiments, this optimal parameter may be written to the recipe to indicate a minimum pressure, such as shown in process parameter value 118 of FIG. 1.

In some embodiments, an optimal parameter value may overwrite a process parameter value to change a recipe. In some embodiments, a process parameter value may be overwritten based on a health indicator. For example, if a pressure value of a recipe is less than a pressure value determined as a minimum optimal process parameter value, then the pressure may be adjusted to the optimal pressure value determined in block 212. In some embodiments, the optimal parameter values may be written to a recipe after a verification step to determine the optimal parameter values result in a successful recipe.

The recipe may be performed using the optimal parameter values (216). Performance of a recipe may be used to collect data and confirm that the determined optimal parameter values are valid. For example, as discussed above, a model used to initially validate a recipe may not sufficiently account for variations in implementation of a tool or recipe at a fabrication site. The DOE analysis to determine optimal parameter values, while performed at a fabrication site and thus more accurate than the models used for validation, may differ in performance from the recipe when run as intended for processing substrates. Thus, in some embodiments the recipe may be performed with the optimal parameters to verify it can be stably implemented. Various sensor data may be collected during the performance of the recipe.

Health indicators may be determined from sensor data of the performance of the recipe using the optimal parameter values (218). The health indicators may be similar to health indicators used for determining optimal parameter values, e.g., a RF reflection coefficient as presented in FIG. 5. The health indicator may then be analyzed to determine if each health indicator is within an acceptable range. For example, if the RF reflection coefficient is not within a specified range, the plasma may be determined to be unconfined. Other health indicators may be used. In some embodiments, the health indicators for determining if a recipe is healthy are the same as the health indicators used to initially validate a recipe. In other embodiments, the health indicators are distinct from the health indicators used to initially validate a recipe.

If the recipe is considered healthy, then the optimal parameter values may be saved to the recipe (222). In some embodiments, the optimal parameter values are saved as additional metadata for a process engineer to consider when designing recipes. For example, a recipe margin may be saved that a process engineer may be able to use for understanding how low a pressure a process may be performed at while maintaining a confined plasma. Alternatively, in some embodiments the optimal parameter value may be saved as the process parameter value for a step in the recipe. In such embodiments, the recipe may be saved using the optimal parameter value instead of the prior process parameter value. When performed, the recipe will use the optimal parameter value.

If the recipe is not considered healthy, then a report may be generated based on the health indicators that were not met (224). In some implementations, a health indicator may be a combination of various sensor data, and the report may indicate which sensor contributed the most to a low healthiness score. For example, a health indicator for a plasma confinement may be based on ten or more sensor data, including statistics determined from such sensor data, e.g., average, deviations, maximum/minimum values, etc. In some implementations, a subset of the sensor data may significantly contribute to a low health indicator score. In such implementations, a report may indicate which sensor data contributed the most to the low score. A user may then be able to determine if the recipe is faulty or if the sensor data is faulty, e.g., a sensor or other part is faulty and should be replaced. In some implementations, the report may be used by a process engineer to update a recipe. The recipe may then be passed again through the process flowchart shown in FIGS. 2A and 2B.

FIG. 2C presents another flowchart for determining optimized parameters for a recipe. The same reference numbers may be used to indicate similar operations are performed. A recipe is received (202). In some embodiments, an optional operation may be performed to determine baseline metrics (204).

A step of the recipe may then be performed (258). In some embodiments, this step may be performed as part of developing or qualifying a recipe in a test environment. In some embodiments, the recipe may be performed in a production environment on production wafers. During the performance of the recipe step the step may be optimized or modified to improve performance. Blocks 260, 268, 270, and 252 may be performed during performance of the step of the recipe.

Sensor data associated with the performance of the step may be obtained (260). In some embodiments, sensor data may include measurements of, e.g., current, power, conductance, reflection coefficient, etc. In some embodiments, obtaining sensor data may include performing transformations or statistical analysis, for example, a standard deviation of current over a time period.

The sensor data may be used to determine one or more health indicators (268). Each health indicator may represent whether the step is successfully executing, e.g., can be run stably and without adverse effects such as increasing defects on a wafer. Each health indicator may be based on the obtained sensor data. Each health indicator may be determined based on various calculations of sensor data, including transformations, thresholds, filters, statistical analysis, etc.

Once the one or more health indicators are determined, the step may be analyzed as healthy or not (270). In some embodiments, this determination may be based on the health indicator being outside of a range or threshold value. In some embodiments, healthiness may be based on matching the health indicator determined in 268 to a baseline health indicator. If the recipe is unhealthy, then one or more process parameters of the step are modified based on the sensor data and health indicators (252). After modifying the one or more parameters blocks 260, 268, and 270 may be repeated based on the modified process parameters. If the step is healthy, the process parameters may be saved to the recipe (272).

In some embodiments, the healthiness of a step may be based on a health indicator being below a threshold value. For example, FIG. 6C shows a chart of health indicator score over time for a recipe. The health indicator is normalized to a value between 0 and 1, where a value of 0.8 or greater indicates a healthy recipe (i.e., larger values are better). In some embodiments, if the health indicator decreases below 0.8, the step is considered unhealthy.

In some embodiments, the step is considered unhealthy if the health indicator decreases below the threshold value for a minimum duration of time. For example, a health indicator may be determined through various steps or states within a step, and one or more process parameters may change, such as gas flow or temperature. The vertical lines 653 indicate step changes where one or more process parameters may be changed, which cause subsequent temporary decreases in the health indicator. These changes may be reflected in the sensor data being collected and potentially decrease the health indicator, but the health indicator quickly increases after the changes are made as the process chamber stabilizes to the new process parameters. For example, the spikes 650 show a momentary decrease in health indicator score that quickly increases above the 0.8 threshold. In such embodiments, a temporary decrease in the health indicator may be considered acceptable.

In other embodiments, after changing one or more process parameters the health indicator may decrease and stay decreased for a duration, e.g., at least 3 seconds, which may indicate that the step associated with that time index is unhealthy. Box 655 shows a decrease in the health indicator score that remains for about 5 seconds, indicating that the step is unhealthy rather than simply transitioning to a different state. In some embodiments, a health indicator may be used to indicate a step (or a state within a step) is unhealthy based on the health indicator being below the threshold value for a minimum duration of time, as noted above. In some embodiments, the health indicator may be ignored for a duration after a new step is started or process parameters are changed, as the health indicator is expected to fluctuate. Thus, a health indicator may not be used for determining a step is unhealthy for the first, e.g., 1, 2, 3, or 4 seconds after a new step or state is initiated.

In some embodiments, the chart of FIG. 6C may itself be used as a baseline metric. In some embodiments, a recipe may be validated or performed on a tool or process chamber having a particular fingerprint, and the recipe is then performed on a different tool having the same fingerprint. In some embodiments, time series health indicator charts produced when performing the recipe on different tools may be different despite the tools having the same fingerprint. The recipe may perform differently on different tools for various reasons, including differences in wear of consumable parts, different degradation of physical components, or differences in software configurations that are still considered the same fingerprint (e.g., the fingerprint may be defined as having at least software version 1.2, but one tool may have version 1.2.4 and another tool has version 1.2.5). It may be desirable to tune the recipe to produce the same time series health indicator across different tools having the same fingerprint.

Thus, in some embodiments, a time series chart such as shown in FIG. 6C may be used as the baseline metric. In such embodiments, a current time series health indicator chart would be determined as part of block 258 and/or blocks 206-212. The current time series health indicator chart may be compared to a baseline time series health indicator chart, and a comparative health indicator generated based on the difference between the current and baseline health indicator. If the comparative health indicator exceeds a threshold value, e.g., a value of 0.05 for [0,1] normalized health indicators, then the step or state may be considered as unhealthy for failing to match the baseline metric, even if the current health indicator is above a threshold value as shown in FIG. 6C. Conversely, a current health indicator may drop below the threshold value that may otherwise indicate unhealthiness and still be considered healthy as it matches the baseline health indicator (which is also below the threshold value but may still be considered healthy, e.g., it is below the threshold value for less than a pre-determined duration as noted above).

In some embodiments, the impact of various process parameters on health indicators may be determinable based on one or more relationships between a process parameter, sensor data, and the health indicator. For example, returning to FIG. 5, pressure may be known to affect RF reflection coefficient, and a desired range of values for the RF reflection coefficient is previously determined. If the RF reflection coefficient is outside of this range, then the health indicator may move outside a threshold value. In some embodiments, when the health indicator changes to be considered unhealthy, the RF reflection coefficient may be determined as contributing to the unhealthy score and a process parameter, such as pressure, may be modified to change the RF reflection coefficient to be within the desired range.

While the impact of some process parameters on health indicators may be generally understood, it may be difficult to model given the large quantity of sensor data available. For example, tens or hundreds of process parameters may be set for a given step of a recipe, and a health indicator may be based on sensor data relating to various different process parameters. Thus, it is difficult to understand how changing a process parameter will affect a health indicator. Using methods disclosed herein, process parameters may be optimized empirically by modifying them to optimize a health indicator.

In some embodiments, the loop of blocks 260, 268, 270, and 252 may be repeated until one or more health indicators converge on optimal values. For example, a health indicator may be treated as an outcome of an objective function, and the one or more process parameters may be modified to minimize/maximize the health indicator value. Thus, if increasing a process parameter, for example pressure, decreases the health indicator, then the pressure may be increased instead. Once the health indicator converges on a local maximum/minimum, the one or more process parameters that have been modified may be considered optimal and saved to the recipe.

While examples presented herein discuss modifying one or two parameters, it should be understood that a step of a recipe may include tens or hundreds of parameter values that can be modified. In some embodiments, a subset of such parameters may be selected for optimizing by the process shown in FIG. 2C. This may then be repeated for different subsets of parameters and different steps of a recipe.

In some embodiments, the process of FIG. 2C may be performed during performance of a step of a recipe without resetting the step to modify process parameters. For example, sensor data may be collected and analyzed in real time to modify process parameters during performance of a step of the recipe, by, e.g., modifying the pressure while a plasma is ignited to measure how RF reflection coefficient changes in response to modifying pressure. Modifying process parameters while performing a step may increase throughput on finding optimal process parameters by iterating through different parameters faster.

In some embodiments, as noted above, the process of FIG. 2C may be performed as part of developing or qualifying a recipe, i.e., determining a recipe may be stably implemented. In other embodiments, the process of FIG. 2C may be performed during performance of a recipe in a production environment. In some embodiments, the process of FIG. 2C may be used to modify a process parameter when a health indicator indicates the step is unhealthy. For example, if a health indicator indicates the plasma is unstable, the pressure (or other process parameters) may be modified to improve the stability of the plasma and the corresponding health indicator. Process parameters may be changed within a recipe margin and/or according to a model.

FIG. 6A presents a schematic illustration of a health characteristic determination system. The system of FIG. 6A may be used to determine health indicators as described in 218 and 268, above. Sensor data inputs 602 may be identified with input states 604, which may be analyzed by a model to determine output states 606 and processed through combiner logic 608 to generate health characteristics 610. Sensor data inputs 602 may be the same as the sensor data discussed in regard to block 210 and 260, above. In some embodiments, sensor data inputs may represent more than 100 different parameters. Example sensor data inputs are shown in FIG. 6 and include recipe parameters and metrics/sensor data from a bias power generator, voltage sensors, TCP inner and outer coils, etc.

The sensor data inputs may be identified with one or more input states 604. States may represent a particular configuration of hardware and software during a step. In some embodiments, a step may have only one state, and in such embodiments a state and step may be considered synonymous. In other embodiments, a step may have multiple states. For example, a plasma process may have one or more radio-frequency (RF) sources that cycle between a low and high power. In some embodiments, a plasma may be characterized by a pulse that has two or more states, e.g., off/on, off/low power/high power, different powers for each RF source, etc. In such embodiments, it may be desirable to analyze the RF characteristics for each state within a step, rather than analyzing the step as a whole, as each state may be independently optimized or malfunction.

The sensor data may then be analyzed by a model to determine output states 606. Each output state may have a single health indicator score and, in some embodiments, metrics that most contributed to a decrease in the health indicator score, e.g., sensor data that indicates a malfunction. In some embodiments, a step may have a single state, while in other embodiments a step may have multiple states as discussed above. In some embodiments, there is a corresponding output state for each input state.

Combiner logic 608 may then combine health indicator scores and contributing metrics across states and/or steps. For example, health indicator scores may be combined by various statistic techniques, including averages, min/max, or weighted sums. The combined output states may then be presented as a single overall health characteristic for a step or series of steps. For example, a single RF score health indicator may represent the healthiness of an RF system. Various error codes or contributing metrics may be associated with the health indicator and may represent potential causes of the health indicator score. For example, the error codes may indicate which sensor data most contributed to the health indicator score so a process engineer can more quickly diagnose and rectify the cause of the low health indicator score.

In some embodiments, the system of FIG. 6A may be used to optimize parameter values. For example, various parameter values may be provided to the system of FIG. 6 and the health indicator score may be maximized over various combinations of recipe parameter values. In some embodiments, the system of FIG. 6 may be used for determining optimal parameter values as discussed at 212 and 258, above, based on sensor data collected during the performance of a recipe step. As noted above, a step may also have multiple states, which in some embodiments may be similarly analyzed and a health indicator score may be attributed to each state as well as the entire step.

In some embodiments, output states may be determined based on one or more models. For example, in the context of RF metrics, an instability model and a mis-tune model may be used to analyze stability and tuning of the RF pulse shape data, respectively. Various sensor data may be provided to an instability model which determines whether the RF pulse data is stable, based on, e.g., oscillations or spikes around a steady state value. Similarly, sensor data may be provided to a tuning health model that determines how close the steady state values from the sensor data are to the desired setpoints. If the models determine the RF pulse data is unstable and/or mistuned (based on, e.g., sensor data exceeding a threshold), the health indicator score will be negatively impacted and specific error codes relating to stability and tuning may be provided in a report for a process engineer to troubleshoot.

In some embodiments, the system of FIG. 6A may be used to identify root causes of sensor data and/or process parameters that negatively affect health indicators. For example, if sensor data provided to the system of FIG. 6A is processed and a health indicator score indicates the step is unstable, it is desirable to determine what is contributing to the bad health indicator score. However, the sensor data being ingested may be hundreds of different types of data collected over a time period, resulting in thousands of data points to be analyzed. Thus, in some embodiments the system of FIG. 6A may also be configured to determine potential causes of a bad health indicator score.

FIG. 6B depicts an example report explaining potential causes of a bad health indicator. The information shown may be based on a datalog of sensor data and a recipe, which may be analyzed as described herein and particularly in relation to FIG. 6A. A shown in FIG. 6B, step 2 of an example recipe may have a low health indicator score, which is then determined to result from sensor data relating to RF stability for a state 1 (S1) of step 3. In some embodiments a failure mode may be provided. Failure mode may describe why the health indicator score is low. For example, in FIG. 6B, there are failure modes relating to the variability for the bias and TCP settings. In some embodiments, a failure mode may provide information describing a root cause of the low health indicator, e.g., what process parameters or what sensor data is causing the low health indicator.

In some embodiments, a failure mode may include information on a process parameter of the recipe relating to the root cause, e.g., a set point for power. In some embodiments, a failure mode may include information of a specification for the sensor data to be considered healthy, e.g., the step average variability should be less than 1.5% or less than 10%. In some embodiments the failure mode may also provide the sensor data or statistical data derived from sensor data that does not meet the specification, e.g., the step average variability is 4.2% and should be less than 1.5%. In the example of FIG. 6B the failure modes relate to a state 1 of step 2, and there may be additional states during a step or states may alternate during a step, e.g., alternate between a first state and a second state. Additional information about the RF stability for state 1 may be provided, including process parameters relating to RF stability, e.g., power, as well as some additional statistical information. In some embodiments, information on how to improve the health indicator may be provided for, e.g., a process engineer to modify the recipe. In other embodiments, the recipe may be automatically modified as described above in relation to FIG. 2C.

### Context for Disclosed Computational Embodiments

Certain embodiments disclosed herein relate to computational systems for generating and/or using machine learning models. Certain embodiments disclosed herein relate to methods for generating and/or using a machine learning model implemented on such systems. A system for generating a machine learning model may be configured to analyze data for calibrating or optimizing the expressions or relationships used to represent the classification of, source of, or remedies for a defect on a substrate. A system for generating a machine learning model may also be configured to receive data and instructions such as program code representing physical processes occurring during the semiconductor device fabrication operation. In this manner, a machine learning model is generated or programmed on such system. A programmed system for using a machine learning model may be configured to (i) receive input such metrology data of defects on a substrate, and (ii) execute instructions that determine the classification of, source of, or remedies for a defect on the substrate.

Many types of computing systems having any of various computer architectures may be employed as the disclosed systems for implementing machine learning models and algorithms for generating and/or optimizing such models. For example, the systems may include software components executing on one or more general purpose processors or specially designed processors such as Application Specific Integrated Circuits (ASICs) or programmable logic devices (e.g., Field Programmable Gate Arrays (FPGAs)). Further, the systems may be implemented on a single device or distributed across multiple devices. The functions of the computational elements may be merged into one another or further split into multiple sub-modules.

In some embodiments, code executed during generation or execution of a machine learning model on an appropriately programmed system can be embodied in the form of software elements which can be stored in a nonvolatile storage medium (such as optical disk, flash storage device, mobile hard disk, etc.), including a number of instructions for making a computer device (such as personal computers, servers, network equipment, etc.).

At one level a software element is implemented as a set of commands prepared by the programmer/developer. However, the module software that can be executed by the computer hardware is executable code committed to memory using “machine codes” selected from the specific machine language instruction set, or “native instructions,” designed into the hardware processor. The machine language instruction set, or native instruction set, is known to, and essentially built into, the hardware processor(s). This is the “language” by which the system and application software communicates with the hardware processors. Each native instruction is a discrete code that is recognized by the processing architecture and that can specify particular registers for arithmetic, addressing, or control functions; particular memory locations or offsets; and particular addressing modes used to interpret operands. More complex operations are built up by combining these simple native instructions, which are executed sequentially, or as otherwise directed by control flow instructions.

The inter-relationship between the executable software instructions and the hardware processor is structural. In other words, the instructions per se are a series of symbols or numeric values. They do not intrinsically convey any information. It is the processor, which by design was preconfigured to interpret the symbols/numeric values, which imparts meaning to the instructions.

The models used herein may be configured to execute on a single machine at a single location, on multiple machines at a single location, or on multiple machines at multiple locations. When multiple machines are employed, the individual machines may be tailored for their particular tasks. For example, operations requiring large blocks of code and/or significant processing capacity may be implemented on large and/or stationary machines.

In addition, certain embodiments relate to tangible and/or non-transitory computer readable media or computer program products that include program instructions and/or data (including data structures) for performing various computer-implemented operations. Examples of computer-readable media include, but are not limited to, semiconductor memory devices, phase-change devices, magnetic media such as disk drives, magnetic tape, optical media such as CDs, magneto-optical media, and hardware devices that are specially configured to store and perform program instructions, such as read-only memory devices (ROM) and random access memory (RAM). The computer readable media may be directly controlled by an end user or the media may be indirectly controlled by the end user. Examples of directly controlled media include the media located at a user facility and/or media that are not shared with other entities. Examples of indirectly controlled media include media that is indirectly accessible to the user via an external network and/or via a service providing shared resources such as the “cloud.” Examples of program instructions include both machine code, such as produced by a compiler, and files containing higher level code that may be executed by the computer using an interpreter.

In various embodiments, the data or information employed in the disclosed methods and apparatus is provided in an electronic format. Such data or information may include design layouts, fixed parameter values, floated parameter values, feature profiles, metrology results, and the like. As used herein, data or other information provided in electronic format is available for storage on a machine and transmission between machines. Conventionally, data in electronic format is provided digitally and may be stored as bits and/or bytes in various data structures, lists, databases, etc. The data may be embodied electronically, optically, etc.

In certain embodiments, a machine learning model can each be viewed as a form of application software that interfaces with a user and with system software. System software typically interfaces with computer hardware and associated memory. In certain embodiments, the system software includes operating system software and/or firmware, as well as any middleware and drivers installed in the system. The system software provides basic non-task-specific functions of the computer. In contrast, the modules and other application software are used to accomplish specific tasks. Each native instruction for a module is stored in a memory device and is represented by a numeric value.

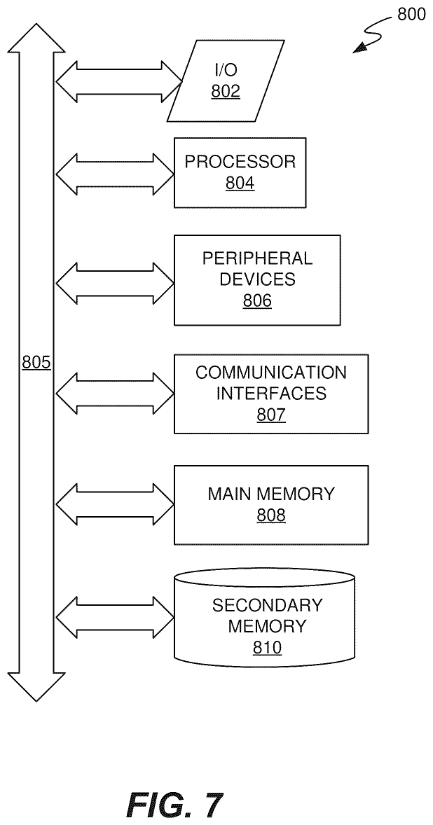

An example computer system 800 is depicted in FIG. 7. As shown, computer system 800 includes an input/output subsystem 802, which may implement an interface for interacting with human users and/or other computer systems depending upon the application. Embodiments of the invention may be implemented in program code on system 800 with I/O subsystem 802 used to receive input program statements and/or data from a human user (e.g., via a GUI or keyboard) and to display them back to the user. The I/O subsystem 802 may include, e.g., a keyboard, mouse, graphical user interface, touchscreen, or other interfaces for input, and, e.g., an LED or other flat screen display, or other interfaces for output. Other elements of embodiments of the disclosure, such as the order placement engine 208, may be implemented with a computer system like that of computer system 800, perhaps, however, without I/O.

Program code may be stored in non-transitory media such as persistent storage 810 or memory 808 or both. One or more processors 804 reads program code from one or more non-transitory media and executes the code to enable the computer system to accomplish the methods performed by the embodiments herein, such as those involved with generating or using a process simulation model as described herein. Those skilled in the art will understand that the processor may accept source code, such as statements for executing training and/or modelling operations, and interpret or compile the source code into machine code that is understandable at the hardware gate level of the processor. A bus couples the I/O subsystem 802, the processor 804, peripheral devices 806, memory 808, and persistent storage 810.

In various embodiments, the computer system 800 may be part of or connected to a controller that is employed to control process conditions during various etch and deposition operations. The controller will typically include one or more memory devices and one or more processors. A processor may include a CPU or computer, analog and/or digital input/output connections, stepper motor controller boards, etc.

The controller may control all of the activities of a deposition and/or etch apparatus. The system controller executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller may be employed in some embodiments.

Typically there will be a user interface associated with the controller. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling species flow, RF power, pedestal temperature, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller. The signals for controlling the process are output on the analog and digital output connections of the deposition and/or etch apparatus.

The system software may be designed or configured in many different ways. For example, various chamber component subroutines or control objects may be written to control operation of the chamber components necessary to carry out the deposition and/or etch processes (and other processes, in some cases) in accordance with the disclosed embodiments. Examples of programs or sections of programs for this purpose include substrate positioning code, process gas control code, pressure control code, and heater control code.

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 629, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Conclusion

In the description, numerous specific details were set forth in order to provide a thorough understanding of the presented embodiments. The disclosed embodiments may be practiced without some or all of these specific details. In other instances, well-known process operations were not described in detail to not unnecessarily obscure the disclosed embodiments. While the disclosed embodiments were described in conjunction with the specific embodiments, it will be understood that the specific embodiments are not intended to limit the disclosed embodiments.

Unless otherwise indicated, the method operations and device features disclosed herein involves techniques and apparatus commonly used in metrology, semiconductor device fabrication technology, software design and programming, and statistics, which are within the skill of the art.

Unless defined otherwise herein, all technical and scientific terms used herein have the same meaning as commonly understood by one of ordinary skill in the art. Various scientific dictionaries that include the terms included herein are well known and available to those in the art. Although any methods and materials similar or equivalent to those described herein find use in the practice or testing of the embodiments disclosed herein, some methods and materials are described.

Numeric ranges are inclusive of the numbers defining the range. It is intended that every maximum numerical limitation given throughout this specification includes every lower numerical limitation, as if such lower numerical limitations were expressly written herein. Every minimum numerical limitation given throughout this specification will include every higher numerical limitation, as if such higher numerical limitations were expressly written herein. Every numerical range given throughout this specification will include every narrower numerical range that falls within such broader numerical range, as if such narrower numerical ranges were all expressly written herein.

The headings provided herein are not intended to limit the disclosure.

As used herein, the singular terms “a,” “an,” and “the” include the plural reference unless the context clearly indicates otherwise. The term “or” as used herein, refers to a non-exclusive or, unless otherwise indicated.

1. A method, comprising:
(a) receiving a first recipe for a semiconductor fabrication operation, the first recipe comprising a plurality of steps, each step having one or more process parameters and each process parameter having a corresponding parameter value;
(b) identifying a step of the first recipe;
(c) performing the step a plurality of times, each performance using different parameter values for one or more process parameters associated with the step;
(d) identifying sensor data associated with each performance of the step;
(e) determining an optimal parameter value for at least one process parameter based on the sensor data; and
(f) associating the optimal parameter value with the first recipe.

2. The method of claim 1, further comprising, before (b), providing the first recipe to one or more validation models, wherein each validation model outputs a health indicator.

3. The method of claim 2, wherein a first validation model outputs a first health indicator that exceeds a first threshold value, wherein the first threshold value represents a threshold where the first recipe may be stably executed.

4. The method of claim 3, further comprising determining, based on the optimal parameter value, that the first recipe may be stably implemented.

5. The method of claim 1, further comprising updating the first recipe based on the optimal parameter value.

6. The method of claim 1, wherein the optimal parameter value represents a recipe margin.

7. The method of claim 1, further comprising
(g) performing the first recipe based on the optimal parameter values, wherein during performance of the first recipe a second health indicator exceeds a second threshold value, and
(h) generating a report indicating the second health indicator exceeded the second threshold value.

8. The method of claim 7, wherein the second health indicator represents a plurality of sensor data, and the report indicates one or more sensor data that most contributed to the second health indicator exceeding the second threshold value.

9. The method of claim 1, wherein the method is performed during qualification of a process recipe.

10. A method, comprising:
(a) receiving a recipe for a semiconductor fabrication operation, the recipe comprising a plurality of steps, each step having one or more process parameters and each process parameter having a corresponding parameter value;
(b) identifying a first step of the first recipe;
(c) performing the first step using a fabrication tool, wherein during performing of the first step one or more cycles are performed of:
(i) identifying sensor data associated with performing the first step;
(ii) determining one or more health indicators based on the sensor data; and
(iii) modifying one or more process parameter values of the first step based on the one or more health indicators and the sensor data.

11. The method of claim 10, wherein the one or more health indicators each represent a plurality of sensor data.

12. The method of claim 10, wherein the one or more cycles are performed until the health indicator converges on a maximum or minimum value.

13. The method of claim 12, wherein the modified one or more process parameter values are saved to the first recipe after the health indicator converges.

14. The method of claim 10, wherein the health indicators are also based on a baseline health indicator metric, wherein the baseline health indicator metric is a health indicator associated with the first step for a prior performance of the first step.

15. The method of claim 14, wherein the prior performance of the first step is with a different fabrication tool than the fabrication tool performing the first step.

16. The method of claim 10, wherein modifying one or more process parameter values of the first step is additionally based on the one or more health indicators exceeding a threshold value.

17. The method of claim 16, wherein modifying one or more process parameter values of the first step is additionally based on the one or more health indicators exceeding the threshold value for a pre-determined duration.

18. The method of claim 10, wherein the one or more cycles are not performed for an initial duration of performing the first step.

19. The method of claim 10, further comprising generating a report of failure modes for the first step of the recipe based on process parameters for the first step and sensor data collected during performance of the first step.

20. The method of claim 19, wherein a first failure mode indicates one or more sensor data that contributed to a first health indicator exceeding a threshold value.

21. A system for optimizing a recipe, comprising:
a process chamber; and
one or more processors configured for:
(a) receiving a recipe for a semiconductor fabrication operation, the recipe comprising a plurality of steps, each step having one or more process parameters and each process parameter having a corresponding parameter value;
(b) identifying a first step of the first recipe;
(c) performing the first step in the process chamber, wherein during performing of the first step one or more cycles are performed of:
(i) identifying sensor data associated with performing the first step;
(ii) determining one or more health indicators based on the sensor data; and
(iii) modifying one or more process parameter values of the first step based on the one or more health indicators and the sensor data.
